(19) United States
(12) Patent Application Publication
(10) Pub. No.: US 2020/0257832 A1
(43) Pub. Date: Aug. 13, 2020

(54) SYSTEM AND METHOD FOR GENERATING FLOOR PLANS

(71) Applicant: RebuildEx, Carver, MA (US)

(72) Inventor: Vittorio M. Artiano, JR., Kingston, MA (US)

(21) Appl. No.: 16/790,154

(22) Filed: Feb. 13, 2020

Related U.S. Application Data
(60) Provisional application No. 62/805,055, filed on Feb. 13, 2019.

(51) Int. Cl. G06F 30/13; G06F 30/12

(52) U.S. Cl. CPC G06F 30/13; G06F 30/12

(57) ABSTRACT

A system and method for generating floor plans is provided. One or more portions of a structure may be scanned. A floor plan may be generated, on a graphical user interface, based upon, at least in part, the scanning of the one or more portions of the structure. One or more labels may be generated, on the graphical user interface, on the floor plan based upon, at least in part, the scanning of the one of more portions of the structure, thus generating a labeled floor plan.

### CROSS REFERENCE TO RELATED APPLICATIONS

The present application claims priority to U.S. Patent Application No. 62/805,055 that was filed on Feb. 13, 2019, entitled “System and Method for Generating Floor Plans” which is hereby incorporated by reference in its entirety.

### BACKGROUND

Floor plans and blueprints are conventionally utilized for the construction and/or maintenance of structures or buildings. However, these floor plans are often changed overtime and do not reflect current uses of rooms or portions of a building. Additionally, it may be difficult to communicate positions within a building to emergency services or other third parties.

### SUMMARY

In one example implementation, a computer-implemented method executed on a computing device may include, but is not limited to, scanning one or more portions of a structure. A floor plan may be generated, on a graphical user interface, based upon, at least in part, the scanning of the one or more portions of the structure. One or more labels may be generated on the floor plan, on the graphical user interface, based upon, at least in part, the scanning of the one of more portions of the structure, thus generating a labeled floor plan.

One or more of the following example features may be included. Scanning the one or more portions of the structure may include generating a plurality of images of the one or more portions of the structure via a camera system. Generating the floor plan may include overlaying the floor plan on an aerial image of the structure. Generating the one or more labels may include overlaying a grid system on the floor plan. Generating the floor plan may include generating and displaying, on the graphical user interface, a navigable three-dimensional model of the structure based upon, at least in part, the scanning of the one or more portions of the structure. The labeled floor plan may be displayed on the graphical user interface while displaying the navigable three-dimensional model of the structure. A viewing orientation indicator configured to dynamically indicate a user's viewing direction within the navigable three-dimensional model of the structure relative to the labeled floor plan may be rendered on the labeled floor plan.

In another example implementation, a computer program product resides on a computer readable medium that has a plurality of instructions stored on it. When executed by a processor, the instructions cause the processor to perform operations that may include, but are not limited to, scanning one or more portions of a structure. A floor plan may be generated, on a graphical user interface, based upon, at least in part, the scanning of the one or more portions of the structure. One or more labels may be generated on the floor plan, on the graphical user interface, based upon, at least in part, the scanning of the one of more portions of the structure, thus generating a labeled floor plan.

One or more of the following example features may be included. Scanning the one or more portions of the structure may include generating a plurality of images of the one or more portions of the structure via a camera system. Generating the floor plan may include overlaying the floor plan on an aerial image of the structure. Generating the one or more labels may include overlaying a grid system on the floor plan. Generating the floor plan may include generating and displaying, on the graphical user interface, a navigable three-dimensional model of the structure based upon, at least in part, the scanning of the one or more portions of the structure. The labeled floor plan may be displayed on the graphical user interface while displaying the navigable three-dimensional model of the structure. A viewing orientation indicator configured to dynamically indicate a user's viewing direction within the navigable three-dimensional model of the structure relative to the labeled floor plan may be rendered on the labeled floor plan.

In another example implementation, a computing system includes at least one processor and at least one memory architecture coupled with the at least one processor, wherein the at least one processor is configured to scan one or more portions of a structure. The at least one processor may be further configured to generate, on a graphical user interface, a floor plan based upon, at least in part, the scanning of the one or more portions of the structure. The at least one processor may be further configured to generate, on the graphical user interface, one or more labels on the floor plan based upon, at least in part, the scanning of the one of more portions of the structure, thus generating a labeled floor plan.

One or more of the following example features may be included. Scanning the one or more portions of the structure may include generating a plurality of images of the one or more portions of the structure via a camera system. Generating the floor plan may include overlaying the floor plan on an aerial image of the structure. Generating the one or more labels may include overlaying a grid system on the floor plan. Generating the floor plan may include generating and displaying, on the graphical user interface, a navigable three-dimensional model of the structure based upon, at least in part, the scanning of the one or more portions of the structure. The labeled floor plan may be displayed on the graphical user interface while displaying the navigable three-dimensional model of the structure. A viewing orientation indicator configured to dynamically indicate a user's viewing direction within the navigable three-dimensional model of the structure relative to the labeled floor plan may be rendered on the labeled floor plan.

This summary is provided to introduce a selection of concepts that are further described below in the detailed description. This summary is not intended to identify essential features of the claimed subject matter, nor is it intended to be used as an aid in limiting the scope of the claimed subject matter.

### BRIEF DESCRIPTION OF THE DRAWINGS

The accompanying drawings, which are included to provide a further understanding of embodiments of the present disclosure and are incorporated in and constitute a part of this specification, illustrate embodiments of the present disclosure and together with the description serve to explain the principles of embodiments of the present disclosure.

FIG. 1 is a diagrammatic view of a distributed computing network including a computing device that executes a floor plan generation process according to an implementation of the present disclosure;

FIG. 2 illustrates a flowchart of a floor plan generation process in accordance with embodiments of various techniques described herein;

FIG. 3 illustrates a three-dimensional model of a structure generated in accordance with embodiments of various techniques described herein;

FIG. 4 illustrates a floor plan of a structure generated in accordance with embodiments of various techniques described herein;

FIGS. 5-6 illustrate labeled floor plans of a structure generated in accordance with embodiments of various techniques described herein;

FIG. 7 illustrates a “doll house” view of a three-dimensional model of a structure generated in accordance with embodiments of various techniques described herein;

FIGS. 8-9 illustrate views of portions of a structure selected from the three-dimensional model of the structure in accordance with embodiments of various techniques described herein;

FIG. 10 illustrates a first portion of a graphical user interface depicting the labeled floor plan generated in accordance with embodiments of various techniques described herein; and

FIGS. 11-12 illustrates a second portion of a graphical user interface depicting interactive labels in accordance with embodiments of various techniques described herein.

Like reference symbols in the various drawings may indicate like elements.

### DETAILED DESCRIPTION

Reference will now be made in detail to the embodiments of the present disclosure, examples of which are illustrated in the accompanying drawings. The present disclosure may, however, be embodied in many different forms and should not be construed as being limited to the embodiments set forth herein. Rather, these embodiments are provided so that this disclosure will be thorough and complete, and will fully convey the concept of the disclosure to those skilled in the art.

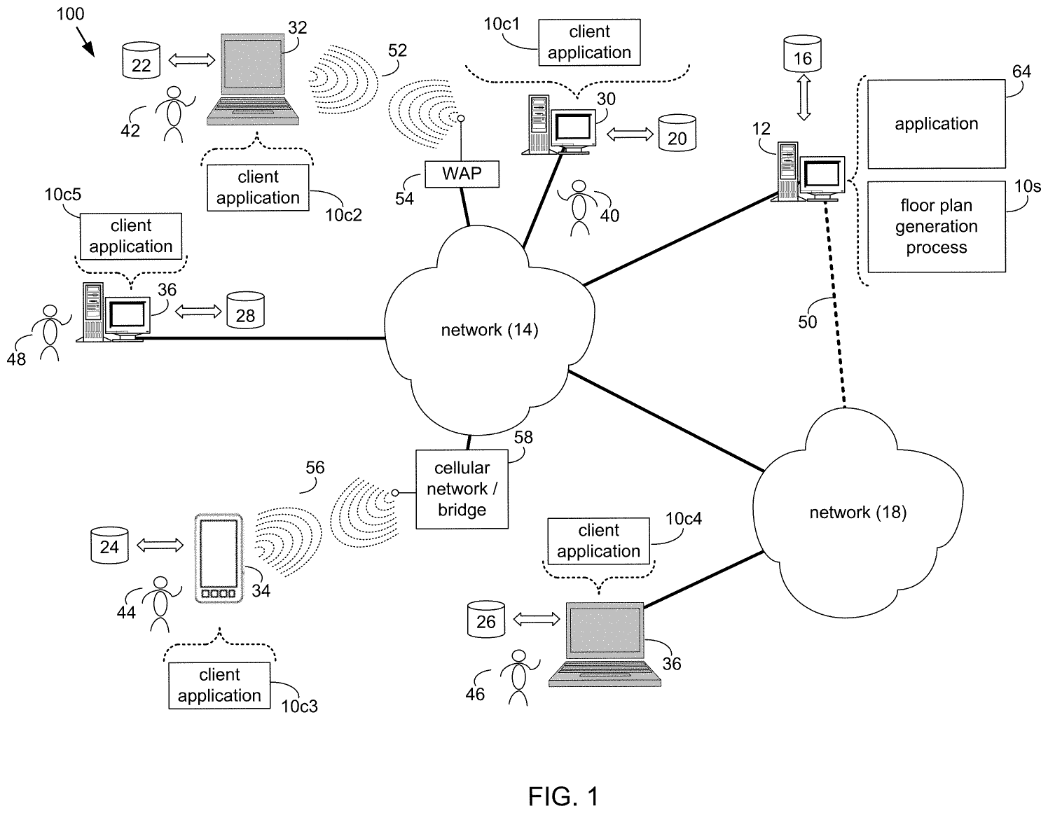

Referring to FIG. 1, there is shown floor plan generation process 10. For the following discussion, it is intended to be understood that floor plan generation process 10 may be implemented in a variety of ways. For example, floor plan generation process 10 may be implemented as a server-side process, a client-side process, or a server-side/client-side process.

For example, floor plan generation process 10 may be implemented as a purely server-side process via floor plan generation process 10s. Alternatively, floor plan generation process 10 may be implemented as a purely client-side process via one or more of client-side application 10c1, client-side application 10c2, client-side application 10c3, and client-side application 10c4. Alternatively still, floor plan generation process 10 may be implemented as a server-side/client-side process via server-side floor plan generation process 10s in combination with one or more of client-side application 10c1, client-side application 10c2, client-side application 10c3, client-side application 10c4, and client-side application 10c5. In such an example, at least a portion of the functionality of floor plan generation process 10 may be performed by floor plan generation process 10s and at least a portion of the functionality of floor plan generation process 10 may be performed by one or more of client-side application 10c1, 10c2, 10c3, 10c4, and 10c5.

Accordingly, floor plan generation process 10 as used in this disclosure may include any combination of floor plan generation process 10s, client-side application 10c1, client-side application 10c2, client-side application 10c3, client-side application 10c4, and client-side application 10c5.

Floor plan generation process 10s may be a server application and may reside on and may be executed by computing device 12, which may be connected to network 14 (e.g., the Internet or a local area network). Examples of computing device 12 may include, but are not limited to: a personal computer, a server computer, a series of server computers, a mini computer, a mainframe computer, or a dedicated network device.

The instruction sets and subroutines of floor plan generation process 10s, which may be stored on storage device 16 coupled to computing device 12, may be executed by one or more processors (not shown) and one or more memory architectures (not shown) included within computing device 12. Examples of storage device 16 may include but are not limited to: a hard disk drive; a tape drive; an optical drive; a RAID device; an NAS device, a Storage Area Network, a random access memory (RAM); a read-only memory (ROM); and all forms of flash memory storage devices.

Network 14 may be connected to one or more secondary networks (e.g., network 18), examples of which may include but are not limited to: a local area network; a wide area network; or an intranet, for example.

The instruction sets and subroutines of client-side application 10c1, 10c2, 10c3, 10c4, 10c5 which may be stored on storage devices 20, 22, 24, 26, 28 (respectively) coupled to client electronic devices 30, 32, 34, 36, 38 (respectively), may be executed by one or more processors (not shown) and one or more memory architectures (not shown) incorporated into client electronic devices 30, 32, 34, 36, 38 (respectively). Examples of storage devices 20, 22, 24, 26, 28 may include but are not limited to: hard disk drives; tape drives; optical drives; RAID devices; random access memories (RAM); read-only memories (ROM), and all forms of flash memory storage devices.

Examples of client electronic devices 30, 32, 34, 36, 38 may include, but are not limited to, personal computer 30, 36, laptop computer 32, mobile computing device 34, notebook computer 36, a netbook computer (not shown), a server computer (not shown), a gaming console (not shown), a data-enabled television console (not shown), and a dedicated network device (not shown). Client electronic devices 30, 32, 34, 36, 38 may each execute an operating system.

Users 40, 42, 44, 46, 48 may access floor plan generation process 10 directly through network 14 or through secondary network 18. Further, floor plan generation process 10 may be accessed through secondary network 18 via link line 50.

The various client electronic devices (e.g., client electronic devices 28, 30, 32, 34) may be directly or indirectly coupled to network 14 (or network 18). For example, personal computer 28 is shown directly coupled to network 14. Further, laptop computer 30 is shown wirelessly coupled to network 14 via wireless communication channels 52 established between laptop computer 30 and wireless access point (WAP) 54. Similarly, mobile computing device 32 is shown wirelessly coupled to network 14 via wireless communication channel 56 established between mobile computing device 32 and cellular network/bridge 58, which is shown directly coupled to network 14. WAP 48 may be, for example, an IEEE 802.11a, 802.11b, 802.11g, 802.11n, Wi-Fi, and/or Bluetooth device that is capable of establishing wireless communication channel 52 between laptop computer 30 and WAP 54. Additionally, personal computer 34 is shown directly coupled to network 18 via a hardwired network connection.

In some embodiments, floor plan generation process 10 may communicate with, interact with, and/or include a component or module of an application (e.g., application 64).

In an embodiment, the instruction sets and subroutines of application 64 may be stored, e.g., on storage device 16 associated with server computer 12, which executes application 64, and/or another suitable storage device. Further, users (e.g., one or more of users 40, 42, 44, 46, 48) may access application 64 in order to access floor plans of a building. The users may access application 64 via one or more suitable applications, such as client side applications 10c1-10c5 (e.g., which may include a web browser, a client electronic meeting application, or another application) and/or via a different application (not shown). Additionally, while some users are depicted as being connected with server computer 12 (and therefore with electronic application 64) via network 14, which may include the Internet, in other embodiments, one or more users may be directed connected to server computer 12 and/or connected with server computer 12 via, e.g., a local area network and/or similar connection.

As generally discussed above, a portion and/or all of the functionality of floor plan generation process 10 may be provided by one or more of client side applications 10c1-10c5. For example, in some embodiments floor plan generation process 10 (and/or client-side functionality of floor plan generation process 10) may be included within and/or interactive with client-side applications 10c1-10c5, which may include client side electronic applications, web browsers, or another application. Various additional/alternative configurations may be equally utilized.

In some implementations of the present disclosure, floor plans may be generated for a structure or building to provide accurate labeling and an objective reference system for use by emergency services or other third parties when accessing a particular structure or building. For example, many structures or buildings do not have readily accessible floor plans or blueprints. Even if these floor plans are available, they are usually out-of-date and are difficult to reference by emergency services or other third parties. Embodiments of the present disclosure may provide a labeled floor plan and a rendered model of a structure. The labeled floor plan and/or rendered model may provide emergency services or other third parties with an objective reference system for communicating and identifying the location of various portions of a structure or building.

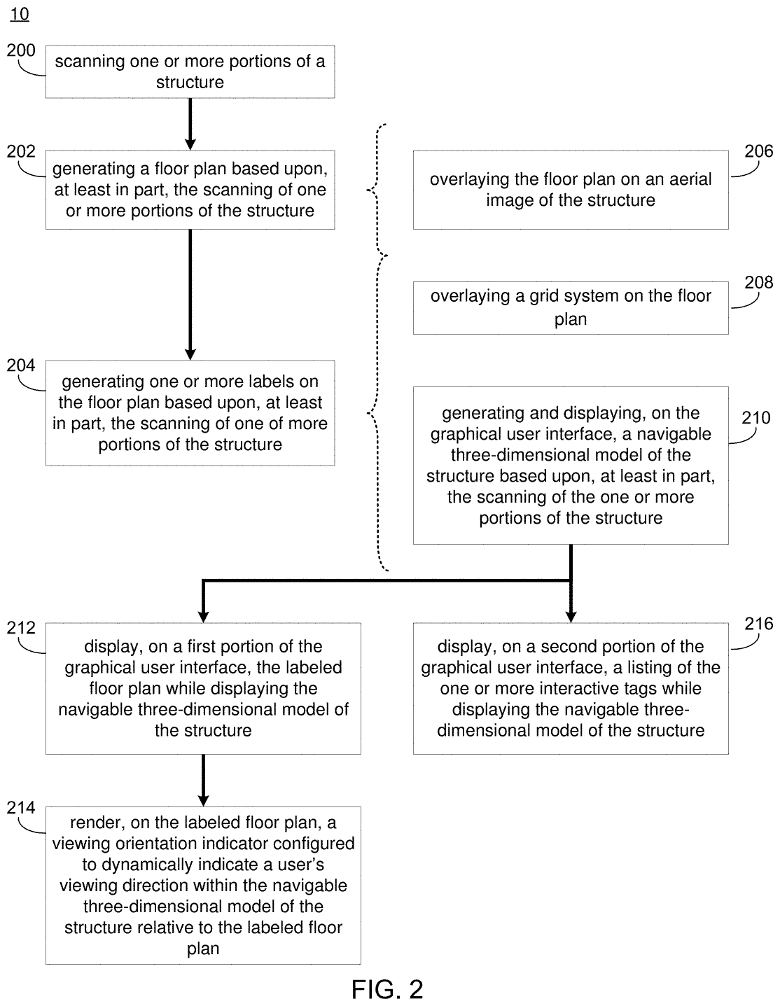

Referring also to FIGS. 2-12 and as will be discussed in greater detail below, floor plan generation process 10 may include scanning 200 one or more portions of a structure. A floor plan may be generated 202 in a graphical user interface based upon, at least in part, the scanning of one or more portions of the structure. One or more labels may be generated 204 on the floor plan in the graphical user interface based upon, at least in part, the scanning of one of more portions of the structure, thus generating a labeled floor plan.

In some implementations, scanning 200 one or more portions of a structure may include accessing the structure. For example, floor plan generation process 10 may include conducting a walkthrough of the structure (e.g., a building, an arena, etc.). In some implementations, preexisting floor plans of building may be gathered. A pre-walkthrough may be conducted and areas may be prepared for scanning Preparing areas of the structure may include opening all doors (e.g., obtaining a master key and propping doors with door stops). Preparing areas may also include turning all available lights in each portion or room of the structure. Scanning the one or more portions of the structure may include hanging one or more tags of a visual fiducial system (e.g., AprilTags) for alignment of the scan. As known in the art, a visual fiduciary system may be useful for a wide variety of tasks including augmented reality, robotics, and camera calibration. These visual fiducial system tags may be placed in various locations throughout the one or more portions of the building. In some implementations, scanning 200 may be conducted piecemeal or, preferably, without interruption.

In some implementations, scanning 200 the one or more portions of the structure may include generating images, videos, drawings, etc. of the portions of the structure. In one embodiment, scanning 200 the one or more portions may include utilizing a Matterport® camera system available from Matterport, Inc. of Sunnyvale, Calif. A Matterport® camera system may generally include a camera system configured to collect a plurality of images and configured to combine them into a three-dimensional model. While a Matterport® camera system has been discussed, it will be appreciated that any camera or video system may be used within the scope of the present disclosure. As will be discussed in greater detail below, the plurality of images may be converted using the camera system into a three dimensional model of a structure. In some implementations, scanning 200 may include generating or capturing a plurality of images of the one or more portions of the structure. In one embodiment utilizing the camera system, scanning 200 a portion of a structure may include creating a new job in a software system and creating a new name space. In some implementations, scanning 200 the one or more portions of the structure may include capturing a 360° scan or a series of images of exterior sides of a structure. An interior scan of a structure may include starting a scan of a portion of a structure by first capturing an image of a reference location (e.g., a doorway). Additional scans may be captured and it may be determined if the scans are in numerical order. All windows, mirrors and trim may be marked and any excess may be removed from the scan with a mobile electronic device.

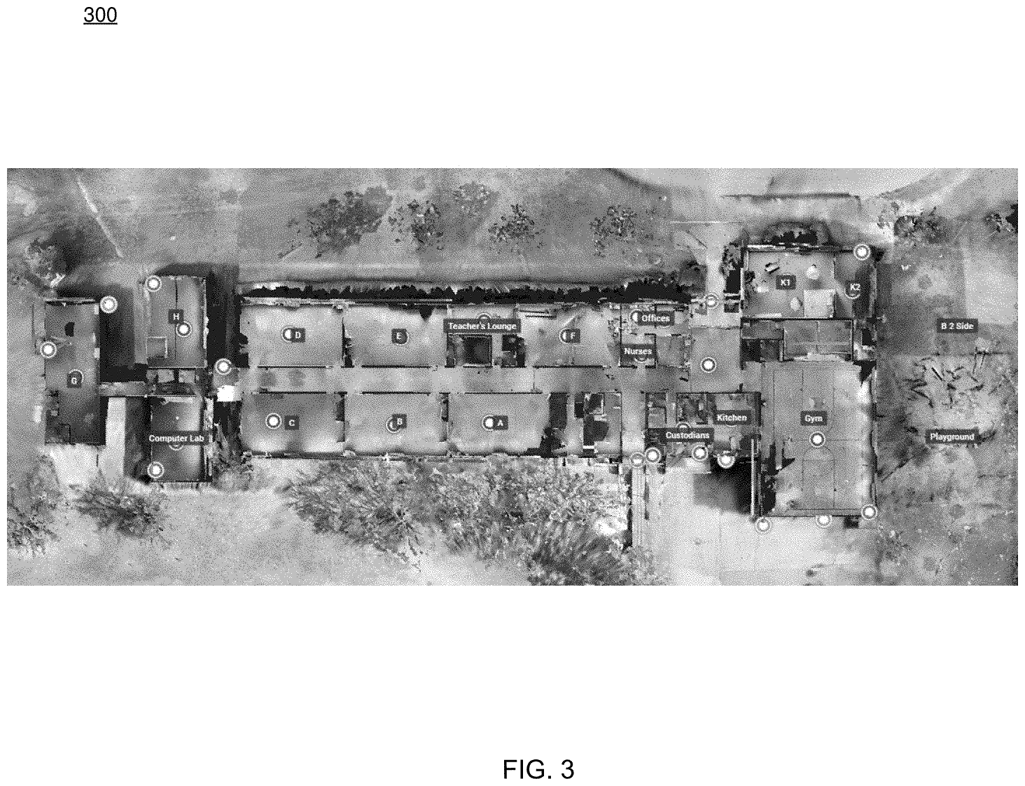

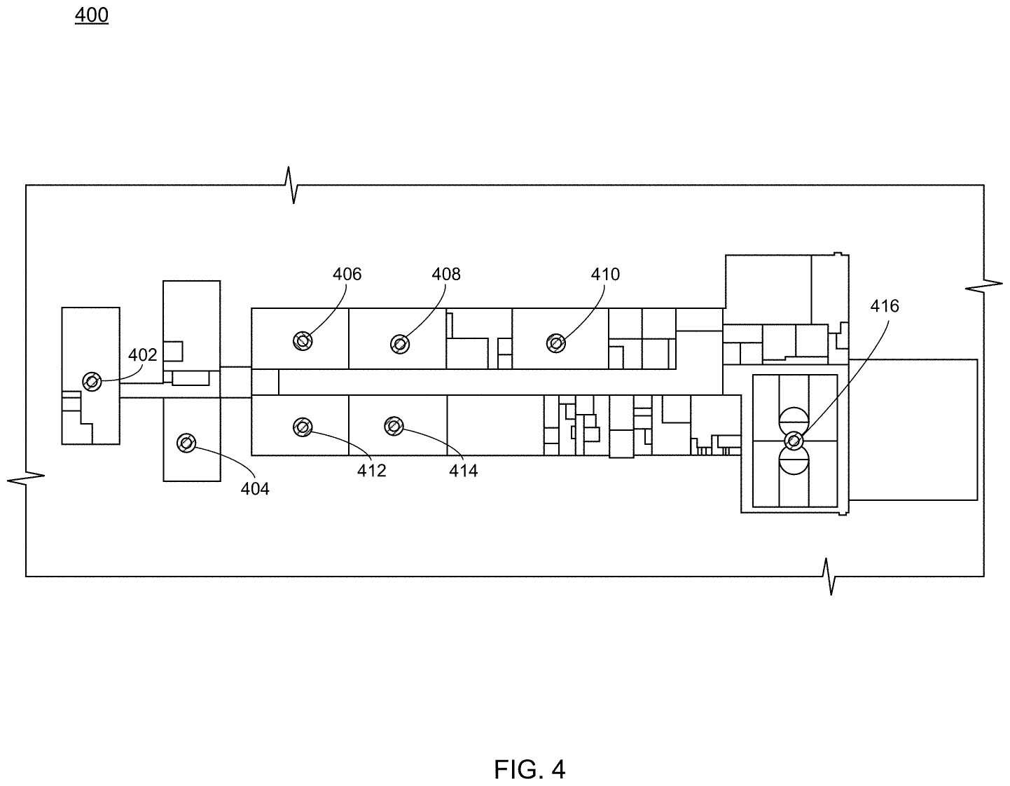

In some implementations, a floor plan may be generated 202 on a graphical user interface based upon, at least in part, the scanning of one or more portions of the structure. Referring also to the example of FIGS. 3-4 and in some implementations, a floor plan of a particular building may be generated 202 based upon, at least in part, scanning of the rooms of the building. For example and in some implementations, generating 202 the floor plan may include uploading and processing the scanned images and/or videos of the one or more portions of the structure into a three-dimensional model of the one or more portions of the structure. For example and as discussed above, portions of a structure may be scanned 200 using a camera system. Referring to the example of FIG. 3, floor plan generation process 10 may generate a model (e.g., three dimensional model 300) using a plurality of images captured by the camera system. In this example, a plurality of images may be combined to form three-dimensional model 300 using one or more systems (e.g., Matterport® camera system and/or related software from Matterport, Inc. of Sunnyvale, Calif.). In some implementations, floor plan generation process 10 may confirm that the space has uploaded accurately during processing and, once processed, checking the rendered three-dimensional model (e.g., three dimensional model 300) for errors. As will be discussed in greater detail below, the three-dimensional model (e.g., three dimensional model 300) may be displayed on a graphical user interface and may be navigable by a user via the graphical user interface.

Referring also to the example of FIG. 4, floor plan generation process 10 may generate 202 a floor plan (e.g., floor plan 400) of a structure using the three-dimensional model of the structure (e.g., three-dimensional model 300). For example and in some implementations, a Matterport® camera system (and/or related software components) may convert the plurality of images into a three-dimensional model of the structure and from the three-dimensional model, may generate a floor plan representative of the structure. While a three-dimensional model generated based upon a Matterport® camera system has been discussed, it will be appreciated that any system or software that converts a plurality of images into a three-dimensional model and floor plan may be used within the scope of the present disclosure.

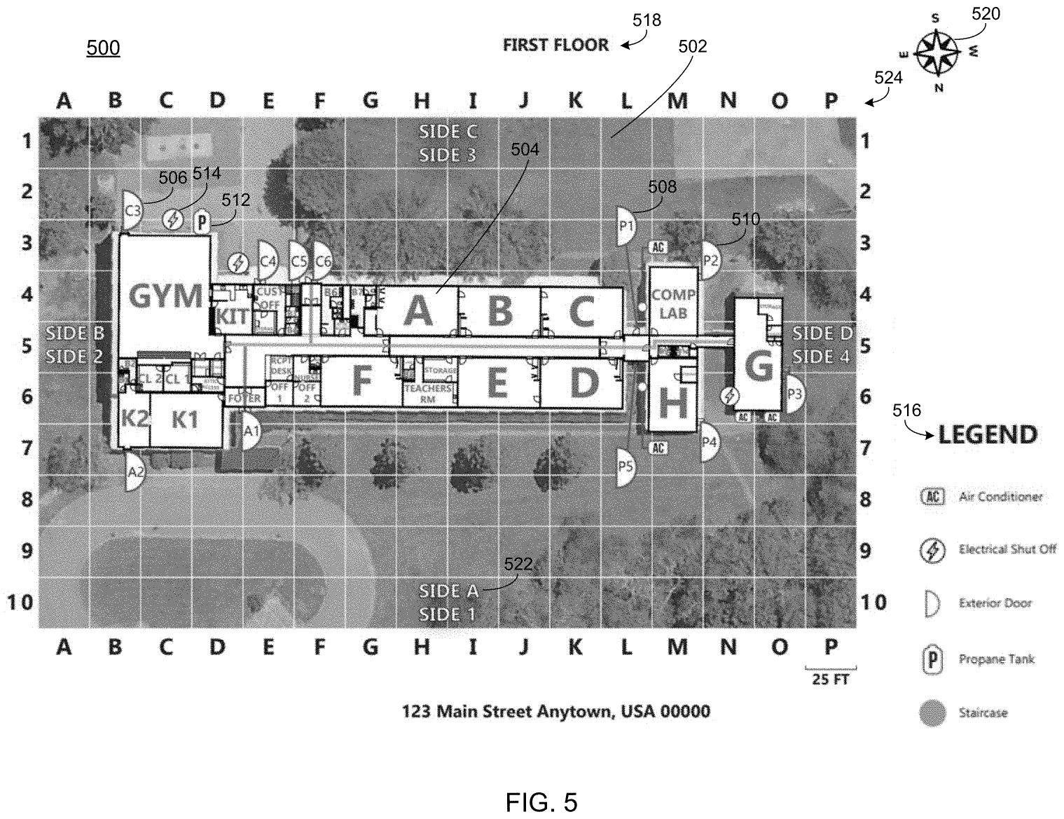

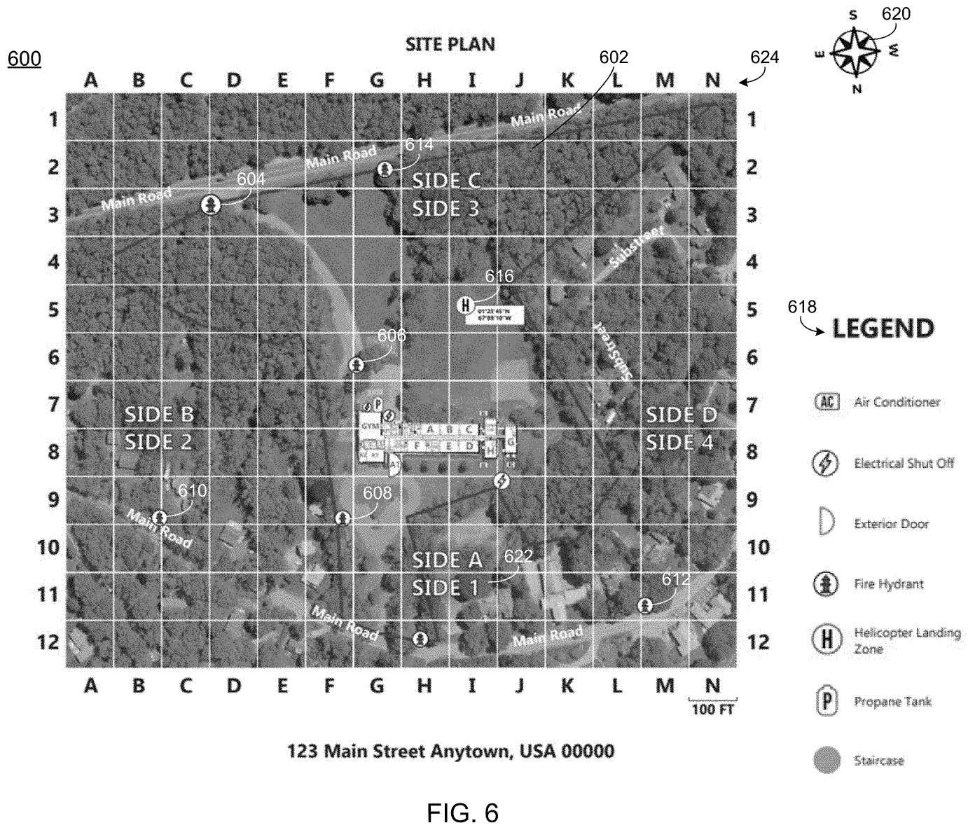

As can be seen from the example of FIG. 4, even with a generated floor plan representative of a structure, it may be difficult for emergency services and/or other third parties to orient themselves within and about the structure. Accordingly, floor plan generation process 10 may generate 202 the floor plan with additional features. For example and in some implementations, generating 202 the floor plan may include overlaying 206 the floor plan on an aerial image of the structure. Referring also to the examples of FIGS. 5-6 and as will be discussed in greater detail below, overlaying 206 the floor plan on an aerial or satellite image of the structure (e.g., aerial image 502, 602), via floor plan generation process 10, may allow emergency services and other third parties to understand the location of portions of the structure relative to natural landmarks, roads, paths, adjacent structures, etc. In this manner and in some implementations, a more complete understanding of the structure may be conveyed by overlaying 206 the floor plan on an aerial image of the structure. As will be discussed in greater detail below, floor plan generation process 10 may generate a plurality of floor plans representative of different views or scopes of a structure. For example, FIG. 5 may demonstrate a labeled floor plan as generated by floor plan generation process 10 that includes labeled features at the structure or floor level while FIG. 6 may demonstrate a labeled floor plan as generated by floor plan generation process 10 that includes labeled features at a property or site level. Accordingly, it will be appreciated that floor plan generation process 10 may generate floors plans with varying levels of granularity or scope.

In some implementations, an aerial image of the structure (e.g., aerial image 502, 602) may be obtained from a vendor, a drone, a camera system, etc. Accordingly, it will be appreciated that an aerial image (e.g., aerial image 502, 602) may be obtained from various sources. In some implementations, the aerial image (e.g., aerial image 502, 602) may include a plurality of aerial or satellite images that may be combined (e.g., by floor plan generation process 10) to represent the surrounding area of a structure.

In some implementations, floor plan generation process 10 may generate 204 one or more labels on the floor plan. Generating 204 the one or more labels may generally include manually or automatically generating labels, symbols, or other markers to the floor plan to identify particular features. In some implementations and referring again to the examples of FIGS. 5-6, generating 204 the one or more labels to the floor plan (e.g., floor plan 500) may include one or more of generating room names and/or numbers (e.g., room label “A” 504); applying a shading color for elevators, stairs hallways; generating labels for exterior doors/emergency exits (e.g., exterior door label 506, 508, 510); generating a label for a gas shutoff location; generating a label for a natural gas and/or heating oil tank (e.g., propane tank label 512); generating a label for a sprinkler shutoff location; generating a label for a water shutoff valve location; generating a label for an electrical panel location; generating a label for electrical disconnect locations (e.g., electrical disconnect label 514); generating labels for fire hydrants (e.g., fire hydrant label 604, 606, 608, 610, 612, 614); generating a label for a helicopter landing zone with coordinates (e.g., helicopter landing zone label 616); generating a label for an elevator control panel; generating a label for a fire control panel; generating a label for any rooftop units; etc. While several emergency service-related labels have been described, it will be appreciated that any label may be generated within the scope of the present disclosure.

In some implementations, generating 204 the one or more labels may include generating a legend of symbols to represent various locations within the structure. For example and referring again to the examples of FIGS. 5-6, floor plan generation process 10 may generate a legend (e.g., legend 516, 618) with symbols to represent various features. In some implementations, the symbols to include in the legend (e.g., legend 516, 618) may be user-defined or automatically predefined by floor plan generation process 10.

In some implementations, generating 204 the one or more labels may include generating the building address; a floor name (e.g., floor label 518); a compass rose (e.g., compass rose 520, 620); a label for each side of the building (e.g., side label 522, 622) starting with Side A/Side 1 and continuing e.g., clockwise); and/or generating labels for exterior landmarks. In some implementations, side label 522, 622 may provide an objective basis for defining and communicating positions of one or more portions of a structure. For example, as opposed to relying on a user's familiarity with a structure, floor plan generation process 10's side labels (e.g., side label 522, 622) may provide a standard reference for emergency services and/or other third parties to reference. In some implementations, each floor of a multi-story building may be saved as a layer of the floor plan. For example, FIG. 5 describes an example of a first floor of a multi-floor building. While different floors may be represented in different labeled floor plans, it will be appreciate

In some implementations, generating 204 the one or more labels may include overlaying 208 a grid system on the floor plan. For example and referring also to the example of FIGS. 5-6, floor plan generation process 10 may overlay 208 or superimpose a grid system with grid numbers and/or letters (e.g., grid system 524, 624) on the floor plan of the structure. In some implementations, floor plan generation process 10 may overlay 208 or superimpose the grid system on the aerial image of the structure (e.g., aerial image 502, 602) in response to overlaying 208 the floor plan on the aerial image of the structure. In this manner, a grid system (e.g., grid system 524, 624) may be utilized to objectively reference positions within the structure. For example, the grid system of FIGS. 5-6 may include a series of columns and rows with labels of numbers and letters to define grids on the floor plan. Accordingly, portions of a building, or even spaces outside of the building, may be identified quickly and objectively using the grid system (e.g., grid system 524, 624).

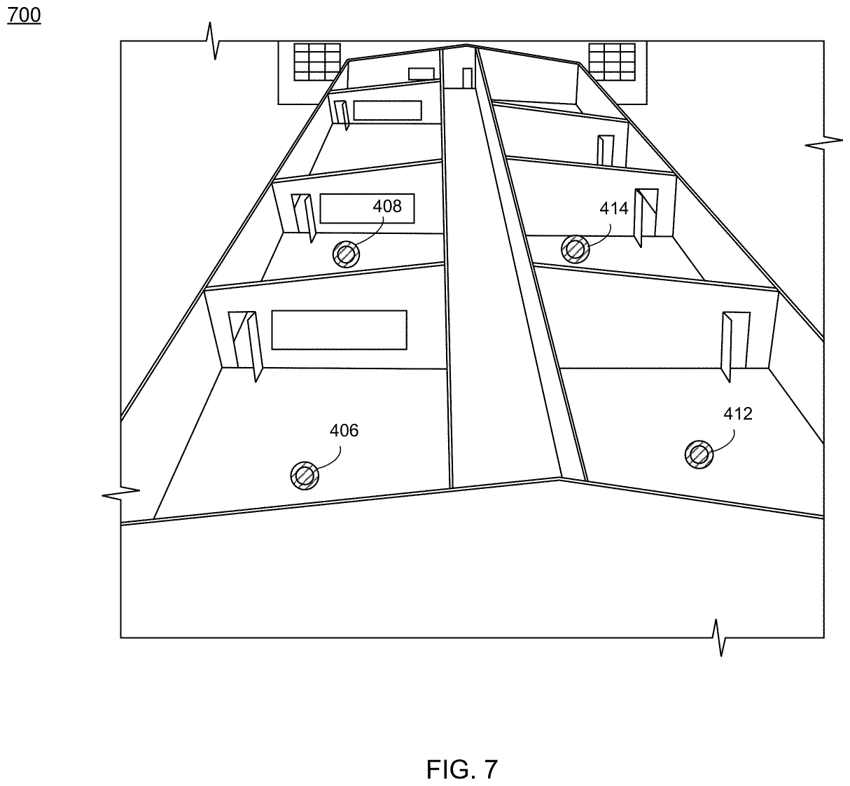

Referring also to the example of FIGS. 7-12 and in some implementations, generating 202 the floor plan may include generating 210 and displaying, on the graphical user interface, a navigable three-dimensional model of the structure based upon, at least in part, the scanning of the one or more portions of the structure. For example and as discussed above, a navigable three-dimensional model of the structure may be generated 210 in a graphical user interface based upon, at least in part, the scanning of the one or more portions of the structure. Referring again to the example of FIG. 3 and in some implementations, the three-dimensional model can be displayed as a floor plan of a structure using images taken of various portions of the structure. As discussed above, the rendered three-dimensional model of FIG. 3 may be generated using a plurality of images of a structure or building. In some implementations, floor plan generation process 10 may allow the navigable three-dimensional model to be viewed in a “doll house” view. Referring also to the example of FIG. 7 and in some implementations, the three-dimensional model may include a “doll-house” view of the structure generated based upon, at least in part, the scanning of the one or more portions of the structure. In some implementations, the view of FIG. 7 may provide a user with a perspective including multiple floors or the ability to see over obstacles or walls.

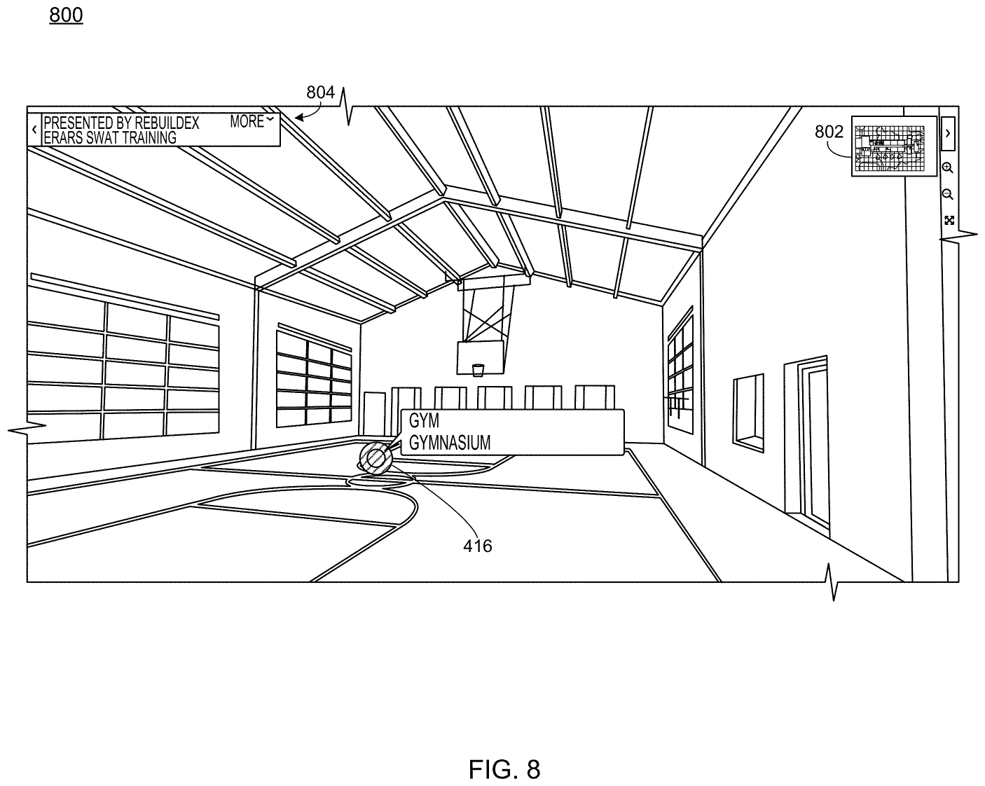

Referring also to FIG. 8 and in some implementations, floor plan generation process 10 may display 210 a navigable three-dimensional model of the structure based upon, at least in part, the scanning of the one or more portions of the structure. In some implementations, a user may navigate, via the graphical user interface, the three-dimensional model of the one or more portions of the structure. In some implementations, floor plan generation process 10 may present e.g., a 360° image of a portion of a structure in the graphical user interface in response to a user selecting the portion of the structure in the three-dimensional model (e.g., three-dimensional model 300). In this manner, a user may access images of portions of a structure while interacting with the three-dimensional model of the structure. In the example of FIG. 8, a user may navigate one or more portions (e.g., gymnasium) of the three-dimensional model (e.g., three-dimensional model 300) of a structure. As discussed above, three-dimensional model 300 may be generated using a plurality of images of the one or more portions of the structure. In some implementations, floor plan generation process 10 may provide controls to allow a user to modify the user's perspective or orientation using e.g., a mouse, a keyboard, voice commands, etc. In this manner, floor plan generation process 10 may provide various controls to allow a user to explore or navigate the one or more portions from various angles or perspectives.

Referring again to the example of FIG. 4 and in some implementations, floor plan generation process 10 may associate one or more interactive tags with one or more portions of the structure. For example, various interactive tags or symbols (e.g., interactive tag 402, 404, 406, 408, 410, 412, 414, 416) may be defined by floor plan generation process 10. In some implementations, while generating the three-dimensional model of a structure (e.g., three-dimensional model 300), floor plan generation process 10 may allow a user to define a plurality of interactive tags within the three-dimensional model. For example, floor plan generation process 10 may receive, via the graphical user interface, a command or indication from a user to generate an interactive tag. In some implementations, floor plan generation process 10 may receive a selection of a portion of the three-dimensional model (e.g., three-dimensional model 300) to associate with the interactive tag. In some implementations, a description or other information to be associated with the interactive tag may be received, via the graphical user interface. In some implementations, selection of an interactive tag (e.g., interactive tag 402, 404, 406, 408, 410, 412, 414, 416) may cause the graphical user interface to display the information associated with the interactive tag. For example and as shown in the example of FIG. 8, suppose interactive tag 416 is predefined to cause the graphical user interface to display information associated with the room of the three-dimensional model. In this example, upon selecting interactive tag 416, floor plan generation process 10 may display the information associated with the room of the three-dimensional model (e.g., information about how the room is a gymnasium). In some implementations, the interactive tags may be used to define relationships between adjacent rooms and security or safety concerns associated with the room or portion of a structure. In some implementations and as will be discussed in greater detail below, floor plan generation process 10 may allow a user to define one or more interactive tag groups and associate one or more interactive tags with the one or more interactive tag groups. For example, a user may define one interactive tag group for e.g., the rooms of a building and another interactive tag group for e.g., exterior doors of a building. It will be appreciated that any number of and/or type of interactive tag group may be defined and used within the scope of the present disclosure.

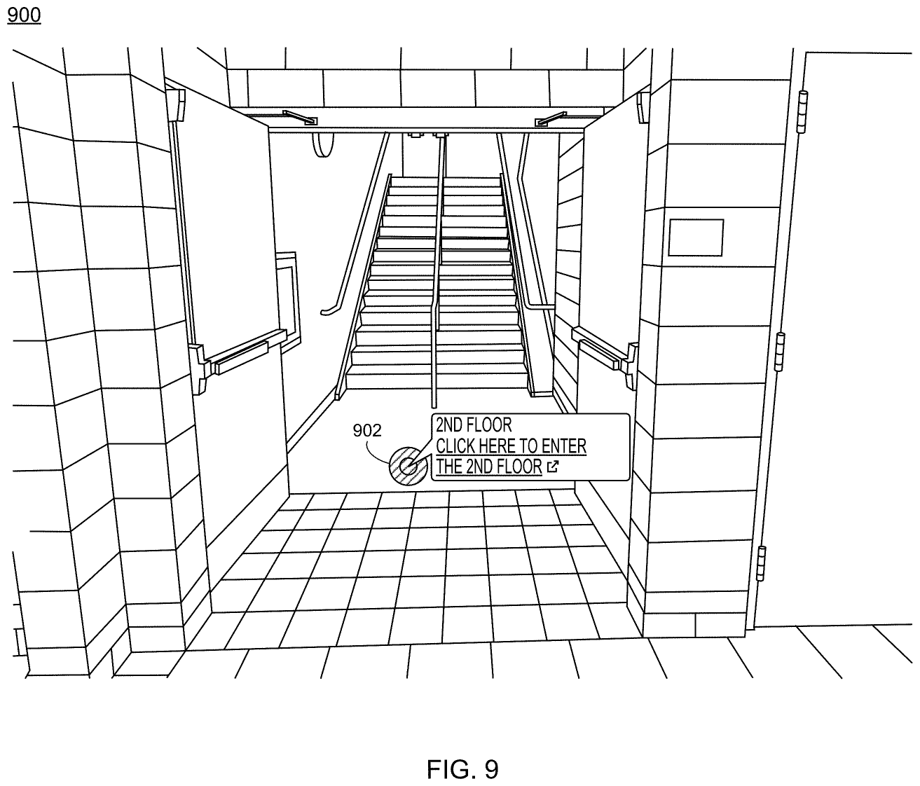

In some implementations, interactive tags may be used to reorient or move a user through the navigable three-dimensional model. Referring also to the example of FIG. 9 and in some implementations, an image of a stairwell from the navigable three-dimensional model may include an interactive tag (e.g., interactive tag 902) that may be configured to “move” the user to a different floor (e.g., a second floor) of the structure. For example, suppose a user selects interactive tag 902. Floor plan generation process 10 may cause the graphical user interface to display one or more images within the three-dimensional model associated with e.g., the second floor of the structure in response to the selection of interactive tag 902. While an example of “movement” between floors has been provided, it will be appreciated that selection of an interactive tag may cause the graphical user interface to display various portions of a structure.

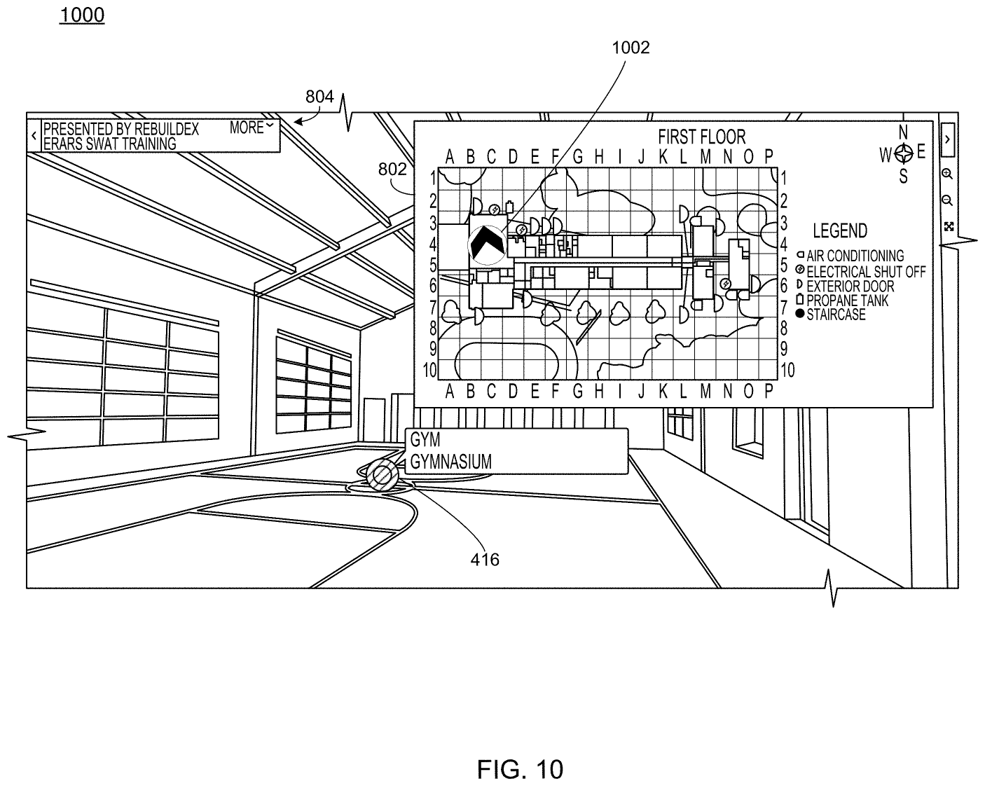

In some implementations, floor plan generation process 10 may display 212, on a first portion of the graphical user interface, the labeled floor plan while displaying the navigable three-dimensional model of the structure. Referring also to the example of FIGS. 8 and 10, floor plan generation process 10 may select a first portion of the graphical user interface (e.g., first portion 802). In some implementations, the first portion of the graphical user interface (e.g., first portion 802) may be configured to be hidden or displayed. For example, when a user is navigating through the navigable three-dimensional model (e.g., three-dimensional model 300), the first portion of the graphical user interface (e.g., first portion 802) may be shown in a minimized window (e.g., as shown in FIG. 8). In response to a user selection of the first portion of the graphical user interface (e.g., first portion 802), the first portion of the graphical user interface (e.g., first portion 802) may expand to a predefined size (e.g., as shown in FIG. 10). In some implementations, the first portion of the graphical user interface (e.g., first portion 802) may have a configurable size within the graphical user interface. As shown in the examples of FIGS. 8 and 10, the first portion of the graphical user interface (e.g., first portion 802) may include the labeled floor plan (e.g., labeled floor plan 500 as shown in FIG. 5). Referring also to the example of FIG. 10, the first portion of the graphical user interface (e.g., first portion 802) may receive a user selection of the one or more portions of the structure as depicted in the labeled floor plan (e.g., labeled floor plan 500). In response to receiving a selection of a portion of the structure within the labeled floor plan (e.g., labeled floor plan 500), floor plan generation process 10 may render the image(s) associated with that selected portion. For example, suppose a user selects the portion of labeled floor plan 500 labeled “GYM”. In this example, floor plan generation process 10 may display the images of the three-dimensional model related to the gymnasium portion of the structure. In some implementations, the first portion of the graphical user interface (e.g., first portion 802) may be a graphical user interface window rendered adjacent to and/or above another graphical user interface window configured to display the images of the structure as the user navigates within the three-dimensional model (e.g., three-dimensional model 300).

In some implementations, floor plan generation process 10 may render 214, on the labeled floor plan, a viewing orientation indicator configured to dynamically indicate a user's viewing direction within the navigable three-dimensional model of the structure relative to the labeled floor plan. Referring again to the example of FIG. 10 and in some implementations, the labeled floor plan (e.g., labeled floor plan 500) displayed in the first portion of the graphical user interface (e.g., first portion 802) may include a viewing orientation indicator (e.g., a viewing orientation indicator 1002) configured to dynamically indicate a user's viewing direction within the navigable three-dimensional model (e.g., three-dimensional model 300) of the structure relative to the labeled floor plan (e.g., labeled floor plan 500). As shown in the example of FIG. 10, suppose a user, e.g., via a mouse, keyboard, voice command, etc., pans and moves around within the portion of the structure (e.g., the gymnasium as shown in FIG. 10). As the user pans around within the room, the viewing orientation indicator (e.g., viewing orientation indicator 1002) rendered 214 on the labeled floor plan (e.g., labeled floor plan 500) within the first portion of the graphical user interface (e.g., first portion 802) may dynamically turn to point in the direction of the user's vantage point relative to the labeled floor plan (e.g., labeled floor plan 500). In some implementations and as the user moves around within the room, the location of the viewing orientation indicator (e.g., a viewing orientation indicator 1002) may change to reflect the user's location within the room. While an example viewing orientation indicator has been shown in the example of FIG. 10, it will be appreciated that various viewing orientation indicators may be used within the scope of the present disclosure. For example, viewing orientation indicator (e.g., a viewing orientation indicator 1002) may include a compass figure or other indicator that can represent or indicate a user's orientation within the three-dimensional model relative to the labeled floor plan displayed in the first portion of the graphical user interface.

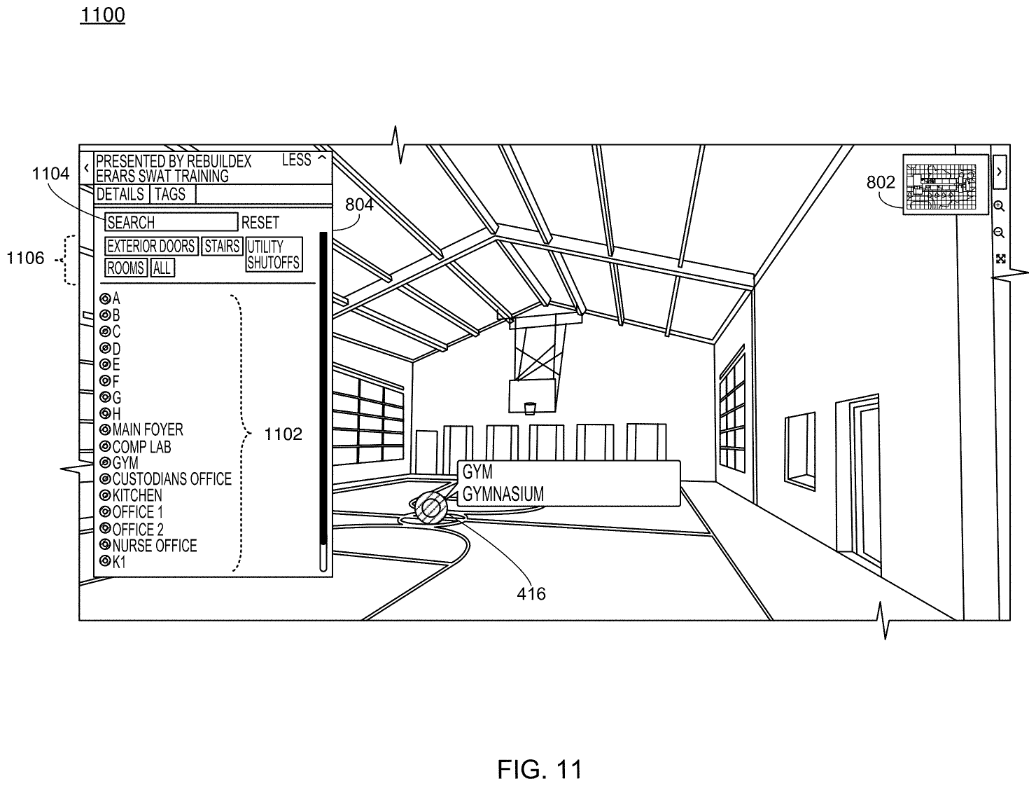

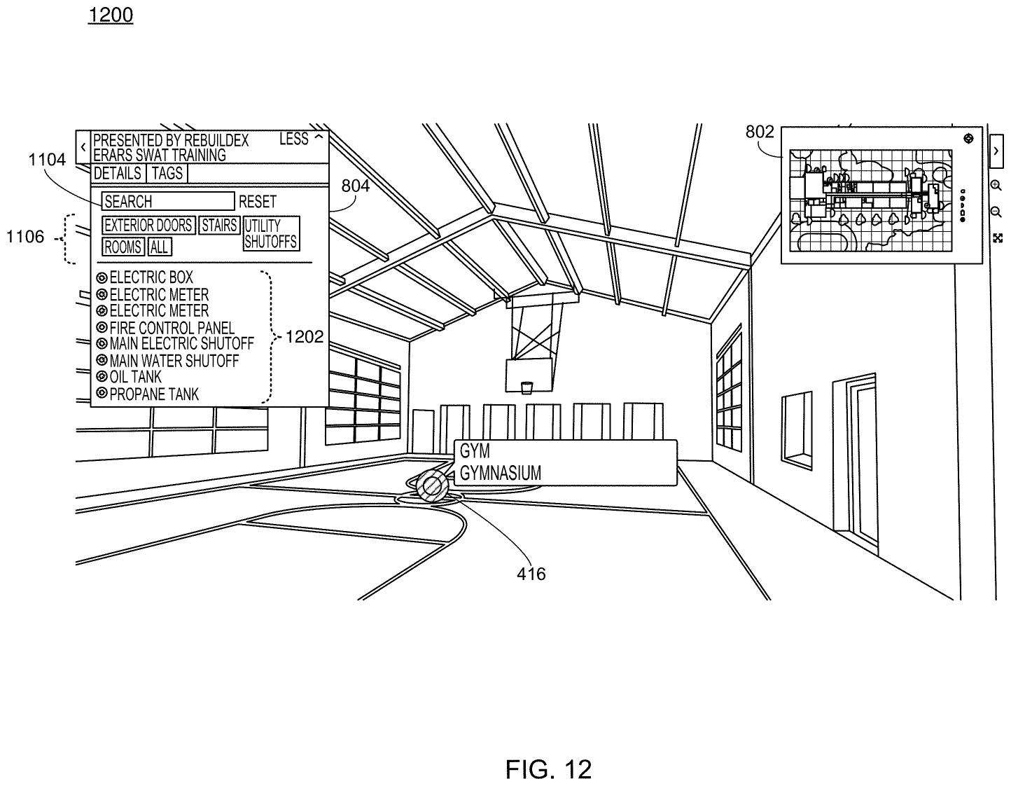

In some implementations, floor plan generation process 10 may display 216, on a second portion of the graphical user interface, a listing of the one or more interactive tags while displaying the navigable three-dimensional model of the structure. Referring to the example of FIGS. 8 and 11-12 and in some implementations, floor plan generation process 10 may display 216 a second portion of the graphical user interface (e.g., second portion 804). In some implementations, the second portion of the graphical user interface (e.g., second portion 804) may be configured to be hidden or displayed. For example, when a user is navigating through the navigable three-dimensional model (e.g., three-dimensional model 300), the second portion of the graphical user interface (e.g., second portion 804) may be shown in a minimized window (e.g., as shown in FIG. 8). In response to a user selection of the second portion of the graphical user interface (e.g., second portion 804), the second portion of the graphical user interface (e.g., second portion 804) may expand to a predefined size (e.g., as shown in FIGS. 11-12). In some implementations, the second portion of the graphical user interface (e.g., second portion 804) may have a configurable size within the graphical user interface.

As shown in the examples of FIGS. 11-12, the second portion of the graphical user interface (e.g., second portion 804) may include a listing or menu of interactive tags (e.g., listing of interactive tags 1102). In some implementations, the second portion of the graphical user interface may include a search bar (e.g., search bar 1104) configured to filter or search the interactive tags and one or more interactive tag group buttons (e.g., interactive tag group buttons) configured to filter the display of the interactive tags based upon, at least in part, one or more predefined categories. Referring to the example of FIG. 11, the second portion of the graphical user interface (e.g., second portion 804) may receive a user selection of the one or more interactive tags in the listing of interactive tags (e.g., listing of interactive tags 1102). In response to receiving a selection of an interactive tag, floor plan generation process 10 may render the image(s) associated with that selected interactive tag. In some implementations, the second portion of the graphical user interface (e.g., second portion 804) may be a graphical user interface window rendered adjacent to and/or above another graphical user interface window configured to display the images of the structure as the user navigates within the three-dimensional model (e.g., three-dimensional model 300).

Referring again to the example of FIG. 11, suppose a user selects an interactive tag group button for e.g., utility shutoffs. Referring now to the example of FIG. 12 and in response to the user selection of an interactive tag group button (e.g., interactive tag button for utility shutoffs), floor plan generation process 10 may cause the second portion of the graphical user interface (e.g., second portion 804) to display one or more interactive tags associated with the selected interactive tag group (e.g., interactive tags 1202). While an example of a particular interactive tag group button has been described, it will be appreciated that any interactive tag group button may be used within the scope of the present disclosure.

In some implementations, floor plan generation process 10 may allow the user to collapse or minimize the first portion (e.g., first portion 802) and/or second portion (e.g., second portion 804) of the graphical user interface to create a less obstructed view of the three-dimensional model of the structure (e.g., three-dimensional model 300). In some implementations, the first portion (e.g., first portion 802) and/or second portion (e.g., second portion 804) of the graphical user interface may be minimized and/or collapsed independently of each other.

In some implementations, floor plan generation process 10 may generate a document (e.g., a PDF) of the labeled floor plan with a link (e.g., a QR code) to the rendered three-dimensional model of the structure (e.g., as shown in FIG. 3). In this manner, a user may be able to access the three-dimensional model of a building in addition to the labeled floor plan of FIGS. 5-6.

As will be appreciated by one skilled in the art, the present disclosure may be embodied as a method, system, or computer program product. Accordingly, the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be utilized. The computer readable medium may be a computer readable signal medium or a computer readable storage medium. A computer-usable, or computer-readable, storage medium (including a storage device associated with a computing device or client electronic device) may be, for example, but not limited to, an electronic, magnetic, optical, electromagnetic, infrared, or semiconductor system, apparatus, or device, or any suitable combination of the foregoing. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device. In the context of this document, a computer-usable, or computer-readable, storage medium may be any tangible medium that can contain, or store a program for use by or in connection with the instruction execution system, apparatus, or device.

A computer readable signal medium may include a propagated data signal with computer readable program coded embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable medium may be transmitted using any appropriate medium, including but not limited to wireless, wireline, optical fiber optic cable, RF, etc., or any suitable combination of the foregoing.

Computer program code for carrying out operations of the present disclosure may be written in an object oriented programming language such as Java, Smalltalk, C″ or the like. However, the computer program code for carrying out operations of the present disclosure may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network (LAN) or a wide area network (WAN), or the connection may be made to an external computer (for example, through the Internet using an Internet Service Provider).

The present disclosure is described below with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable memory that can direct a computer or other programmable data processing apparatus to function in a particular manner, such that the instructions stored in the computer-readable memory produce an article of manufacture including instructions which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

What is claimed is:

1. A computer-implemented method for generating floor plans comprising:
scanning one or more portions of a structure;
generating, on a graphical user interface, a floor plan based upon, at least in part, the scanning of the one or more portions of the structure; and
generating, on the graphical user interface, one or more labels on the floor plan based upon, at least in part, the scanning of the one of more portions of the structure, thus generating a labeled floor plan.

2. The computer-implemented method of claim 1, wherein scanning the one or more portions of the structure includes generating a plurality of images of the one or more portions of the structure via a camera system.

3. The computer-implemented method of claim 1, wherein generating the floor plan includes overlaying the floor plan on an aerial image of the structure.

4. The computer-implemented method of claim 1, wherein generating the one or more labels includes overlaying a grid system on the floor plan.

5. The computer-implemented method of claim 1, wherein generating the floor plan includes generating and displaying, on the graphical user interface, a navigable three-dimensional model of the structure based upon, at least in part, the scanning of the one or more portions of the structure.

6. The computer-implemented method of claim 5, further comprising:
displaying, on a first portion of the graphical user interface, the labeled floor plan while displaying the navigable three-dimensional model of the structure.

7. The computer-implemented method of claim 6, further comprising:
rendering, on the labeled floor plan, a viewing orientation indicator configured to dynamically indicate a user's viewing direction within the navigable three-dimensional model of the structure relative to the labeled floor plan.

8. A computer program product residing on a non-transitory computer readable medium having a plurality of instructions stored thereon which, when executed by a processor, cause the processor to perform operations comprising:
scanning one or more portions of a structure;
generating, on a graphical user interface, a floor plan based upon, at least in part, the scanning of the one or more portions of the structure; and
generating, on the graphical user interface, one or more labels on the floor plan based upon, at least in part, the scanning of the one of more portions of the structure, thus generating a labeled floor plan.

9. The computer program product of claim 8, wherein scanning the one or more portions of the structure includes generating a plurality of images of the one or more portions of the structure via a camera system.

10. The computer program product of claim 8, wherein generating the floor plan includes overlaying the floor plan on an aerial image of the structure.

11. The computer program product of claim 8, wherein generating the one or more labels includes overlaying a grid system on the floor plan.

12. The computer program product of claim 8, wherein generating the floor plan includes generating and displaying, on the graphical user interface, a navigable three-dimensional model of the structure based upon, at least in part, the scanning of the one or more portions of the structure.

13. The computer program product of claim 12, wherein the operations further comprise:
displaying, on a first portion of the graphical user interface, the labeled floor plan while displaying the navigable three-dimensional model of the structure.

14. The computer program product of claim 13, wherein the operations further comprise:
rendering, on the labeled floor plan, a viewing orientation indicator configured to dynamically indicate a user's viewing direction within the navigable three-dimensional model of the structure relative to the labeled floor plan.

15. A computing system comprising:
a memory; and
a processor configured to scan one or more portions of a structure, the processor further configured to generate, on a graphical user interface, a floor plan based upon, at least in part, the scanning of the one or more portions of the structure, and the processor further configured to generate, on the graphical user interface, one or more labels on the floor plan based upon, at least in part, the scanning of the one of more portions of the structure, thus generating a labeled floor plan.

16. The computer-implemented method of claim 1, wherein scanning the one or more portions of the structure includes generating a plurality of images of the one or more portions of the structure via a camera system.

17. The computer-implemented method of claim 1, wherein generating the floor plan includes overlaying the floor plan on an aerial image of the structure.

18. The computer-implemented method of claim 1, wherein generating the one or more labels includes overlaying a grid system on the floor plan.

19. The computer-implemented method of claim 1, wherein generating the floor plan includes generating and displaying, on the graphical user interface, a navigable three-dimensional model of the structure based upon, at least in part, the scanning of the one or more portions of the structure.

20. The computing system of claim 19, wherein the processor is further configured to:
display, on a first portion of the graphical user interface, the labeled floor plan while displaying the navigable three-dimensional model of the structure.
